(19) United States
(12) Patent Application Publication
(10) Pub. No.: US 2021/0357612 A1
(43) Pub. Date: Nov. 18, 2021

(54) FINGERPRINT SENSOR, METHOD OF MANUFACTURING THE FINGERPRINT SENSOR, AND DISPLAY DEVICE INCLUDING THE FINGERPRINT SENSOR

(71) Applicant: Samsung Display Co., LTD., Yongin-si (KR)

(72) Inventors: Yong Hoon YANG, Hwaseong-si (KR); Si Kwang Kim, Daegu (KR)

(21) Appl. No.: 17/157,870

(22) Filed: Jan. 25, 2021

(30) Foreign Application Priority Data
May 18, 2020 (KR) 10-2020-0059154

(51) Int. Cl. G06K 9/00; G02B 6/42; H01L 27/32; H01L 27/146

(52) U.S. Cl. CPC G06K 9/0004; G02B 6/42; G02B 6/4206; G02B 6/4298; H01L 27/14685; H01L 27/3244; H01L 27/14625; H01L 27/14678; H01L 27/3234

(57) ABSTRACT

A fingerprint for a display device includes: a light sensor including a light sensing element through which a sensing current flows according to the intensity of incident light; and a light guide disposed on the light sensor. The light guide includes: a first light blocking member having a first opening; a first light transmitting member disposed on the first light blocking member; and a second light blocking member disposed on the first light transmitting member and having a second opening overlapping the first opening.

### CROSS-REFERENCE TO RELATED APPLICATION

This application claims priority from and the benefit of Korean Patent Application No. 10-2020-0059154, filed on May 18, 2020, which is hereby incorporated by reference for all purposes as if fully set forth herein.

### BACKGROUND

### Field

Embodiments of the invention relate generally to a sensor included in a display device, and more specifically, to a fingerprint sensor and a display device including the same, and a method for driving the same.

### Discussion of the Background

Display devices are being applied to various electronic devices such as smartphones, tablets, notebook computers, monitors, and televisions. Recently, the development of mobile communication technology has greatly increased the use of portable electronic devices such as smartphones, tablets, and notebook computers. A portable electronic device stores personal information such as contact information, call history, messages, photographs, memos, user's web surfing information, location information, and financial information. Therefore, fingerprint authentication is used to authenticate a fingerprint which is a user's biometric information in order to protect the privacy of the user's personal information stored on a portable electronic device. In this case, a display device may include a fingerprint sensor for fingerprint authentication. A fingerprint sensor may be implemented as an optical, ultrasonic, or capacitive fingerprint sensor. An optical fingerprint sensor may include a collimator which has a light sensing part for sensing light, an opening for providing light to the light sensing part, and a light blocking part for blocking light.

When the light blocking part of the collimator is made of photosensitive resin capable of blocking light, for example, an organic material including an inorganic black pigment such as carbon black or an organic black pigment, equipment contamination may occur. Therefore, a manufacturing device for forming thin-film transistors cannot be doubly used as a manufacturing device for forming the light blocking part of the collimator. Accordingly, in conventional apparatus, a separate manufacturing device for forming the light blocking part of the collimator has been required.

The above information disclosed in this Background section is only for understanding of the background of the inventive concepts, and, therefore, it may contain information that does not constitute prior art.

### SUMMARY

Fingerprint sensors and display devices including the same constructed according to the principles and embodiments of the invention are capable of being manufactured without adding a separate manufacturing device. For example, a separate device can be avoided by forming the light blocking part in a light guide from a metal material and/or from alternating layers of light blocking and light transmitting materials.

More specifically, according to some embodiments, the light blocking part may be a layer not made of photosensitive resin capable of blocking light (e.g., carbon black or an organic black pigment). Hence, equipment contamination does not occur when the light blocking part is formed. Therefore, the same manufacturing device used to form thin-film transistors and light sensing elements can also be used as a manufacturing device to form the collimator. Thus, a fingerprint sensor including the light guide can be manufactured without adding a separate manufacturing device.

Additional features of the inventive concepts will be set forth in the description which follows, and in part will be apparent from the description, or may be learned by practice of the inventive concepts.

According to one aspect of the invention, a fingerprint sensor for a display device, the fingerprint sensor includes: a light sensor including a light sensing element through which a sensing current flows according to the intensity of incident light; and a light guide disposed on the light sensor. The light guide includes: a first light blocking member having a first opening; a first light transmitting member disposed on the first light blocking member; and a second light blocking member disposed on the first light transmitting member and having a second opening overlapping the first opening.

The second opening may have a size smaller or larger than that of the first opening.

The light sensor may include a light sensing layer, the light guide may include a light guide layer, the first light blocking member may include a first light blocking layer, the first light transmitting member may include a first light transmitting layer, and the second light blocking member may include a second light blocking layer.

The fingerprint sensor may further include a second light transmitting layer disposed on the second light blocking layer; and a third light blocking layer disposed on the second light transmitting layer and having a third opening.

The third opening may overlap the first opening and the second opening, and the third opening may have a size the substantially same as that of the first opening and that of the second opening.

The third opening may overlap the first opening and the second opening, and the third opening may have a size larger than that of the second opening, and the size of the second opening may be larger than that of the first opening.

The third opening may overlap the first opening and the second opening, and the size of the third opening may be smaller than the size of the second opening, and the size of the second opening may be smaller than the size of the first opening.

The first light transmitting layer may have a thickness greater than that of the second light transmitting layer, and at least one of the first, second and third light blocking layers is metallic.

According to another aspect of the invention, a fingerprint sensor for a display device, the fingerprint sensor includes: a light sensor including a light sensing element through which a sensing current flows according to the intensity of incident light; and a light guide disposed on the light sensing layer. The light guide includes: a first light blocking member having a first opening; a first light transmitting member disposed on the first light blocking member; a second light blocking member disposed on the first light transmitting member and having a second opening overlapping the first opening; a second light transmitting member disposed on the second light blocking member; and a third light blocking member disposed on the second light transmitting member and having a third opening. The first light transmitting layer has a thickness greater than that of the second light transmitting member.

The third opening may overlap the first opening and the second opening, and the third opening may have a size substantially the same as that of the first opening and that of the second opening.

The third opening may overlap the first opening and the second opening, and the third opening may have a size larger than that of the second opening, and the second opening may have a size larger than that of the first opening.

The third opening may overlap the first opening and the second opening, and the size of the third opening may be smaller than that of the second opening, and the second opening may have a size smaller than that of the first opening.

According to still another aspect of the invention, a display device includes: a display panel to display an image; and a fingerprint sensor comprising a light sensor including a light sensing element through which a sensing current flows according to the amount of light that passes through the display panel and a light guide disposed on the light sensor. The light guide includes: a first light blocking member having a first opening; a first light transmitting member disposed on the first light blocking member; and a second light blocking member disposed on the first light transmitting member and having a second opening overlapping the first opening.

The second opening may have a size smaller or larger than that of the first opening.

The light sensor may include a light sensing layer, the light guide may include a light guide layer, the first light blocking member may include a first light blocking layer, the first light transmitting member may include a first light transmitting layer, and the second light blocking member may include a second light blocking layer.

The display device may further include a second light transmitting layer disposed on the second light blocking layer; and a third light blocking layer disposed on the second light transmitting layer and having a third opening overlapping the first opening and the second opening.

The first light transmitting layer may have a thickness greater than that of the second light transmitting layer, and at least one of the first, second and third light blocking layers is metallic.

According to still yet another aspect of the invention, a method of manufacturing a fingerprint sensor includes the steps of: forming a light sensing layer including a light sensing element through which a sensing current flows according to the intensity of incident light; forming a first light blocking layer having a first opening on the light sensing layer; forming a first light transmitting layer on the first light blocking layer; and forming a second light blocking layer having a second opening on the first light transmitting layer, the second opening overlapping the first opening. At least one of the first and second light blocking layers is formed from a metallic material

The method may further include the steps of forming a second light transmitting layer on the second light blocking layer; and forming a third light blocking layer having a third opening on the second light transmitting layer. The third opening may overlap the first opening and the second opening, and the third opening may have a size different from that of the first opening and from that of the second opening.

The first light transmitting layer may have a thickness greater than that of the second light transmitting layer.

It is to be understood that both the foregoing general description and the following detailed description are illustrative and explanatory and are intended to provide further explanation of the invention as claimed.

### BRIEF DESCRIPTION OF THE DRAWINGS

The accompanying drawings, which are included to provide a further understanding of the invention and are incorporated in and constitute a part of this specification, illustrate embodiments of the invention, and together with the description serve to explain the inventive concepts.

FIG. 1 is a perspective view of an embodiment of a display device constructed according to the principles of the invention.

FIG. 2 is a perspective view of an embodiment of the fingerprint sensor of FIG. 1.

FIG. 3 is a cross-sectional view of an embodiment of the display panel and the fingerprint sensor taken along line I-I′ of FIG. 1.

FIG. 4 is an enlarged cross-sectional view of an embodiment of the display panel in area A of FIG. 3.

FIG. 5 is an enlarged cross-sectional view of a first embodiment of the fingerprint sensor in area A of FIG. 3.

FIG. 6 is an enlarged cross-sectional view of a second embodiment of the fingerprint sensor in area A of FIG. 3.

FIG. 7 is an enlarged cross-sectional view of a third embodiment of the fingerprint sensor in area A of FIG. 3.

FIG. 8 is an enlarged cross-sectional view of a fourth embodiment of the fingerprint sensor in area A of FIG. 3.

FIG. 9 is an enlarged cross-sectional view of a fifth embodiment of the fingerprint sensor in area A of FIG. 3.

FIG. 10 is an enlarged cross-sectional view of a sixth embodiment of the fingerprint sensor in area A of FIG. 3.

FIG. 11 is an enlarged cross-sectional view of a seventh embodiment of the fingerprint sensor in area A of FIG. 3.

FIG. 12 is a flowchart illustrating a method of manufacturing a fingerprint sensor according to the principles of the invention.

FIGS. 13 through 18 are cross-sectional views for explaining the method of manufacturing the fingerprint sensor of FIG. 12.

### DETAILED DESCRIPTION

In the following description, for the purposes of explanation, numerous specific details are set forth in order to provide a thorough understanding of various embodiments or implementations of the invention. As used herein “embodiments” and “implementations” are interchangeable words that are non-limiting examples of devices or methods employing one or more of the inventive concepts disclosed herein. It is apparent, however, that various embodiments may be practiced without these specific details or with one or more equivalent arrangements. In other instances, well-known structures and devices are shown in block diagram form in order to avoid unnecessarily obscuring various embodiments. Further, various embodiments may be different, but do not have to be exclusive. For example, specific shapes, configurations, and characteristics of an embodiment may be used or implemented in another embodiment without departing from the inventive concepts.

Unless otherwise specified, the illustrated embodiments are to be understood as providing features of varying detail of some ways in which the inventive concepts may be implemented in practice. Therefore, unless otherwise specified, the features, components, modules, layers, films, panels, regions, and/or aspects, etc. (hereinafter individually or collectively referred to as “elements”), of the various embodiments may be otherwise combined, separated, interchanged, and/or rearranged without departing from the inventive concepts.

The use of cross-hatching and/or shading in the accompanying drawings is generally provided to clarify boundaries between adjacent elements. As such, neither the presence nor the absence of cross-hatching or shading conveys or indicates any preference or requirement for particular materials, material properties, dimensions, proportions, commonalities between illustrated elements, and/or any other characteristic, attribute, property, etc., of the elements, unless specified. Further, in the accompanying drawings, the size and relative sizes of elements may be exaggerated for clarity and/or descriptive purposes. When an embodiment may be implemented differently, a specific process order may be performed differently from the described order. For example, two consecutively described processes may be performed substantially at the same time or performed in an order opposite to the described order. Also, like reference numerals denote like elements.

When an element, such as a layer, is referred to as being “on,” “connected to,” or “coupled to” another element or layer, it may be directly on, connected to, or coupled to the other element or layer or intervening elements or layers may be present. When, however, an element or layer is referred to as being “directly on,” “directly connected to,” or “directly coupled to” another element or layer, there are no intervening elements or layers present. To this end, the term “connected” may refer to physical, electrical, and/or fluid connection, with or without intervening elements. Further, the D1-axis, the D2-axis, and the D3-axis are not limited to three axes of a rectangular coordinate system, such as the x, y, and z-axes, and may be interpreted in a broader sense. For example, the D1-axis, the D2-axis, and the D3-axis may be perpendicular to one another, or may represent different directions that are not perpendicular to one another. For the purposes of this disclosure, “at least one of X, Y, and Z” and “at least one selected from the group consisting of X, Y, and Z” may be construed as X only, Y only, Z only, or any combination of two or more of X, Y, and Z, such as, for instance, XYZ, XYY, YZ, and ZZ. As used herein, the term “and/or” includes any and all combinations of one or more of the associated listed items.

Although the terms “first,” “second,” etc. may be used herein to describe various types of elements, these elements should not be limited by these terms. These terms are used to distinguish one element from another element. Thus, a first element discussed below could be termed a second element without departing from the teachings of the disclosure.

Spatially relative terms, such as “beneath,” “below,” “under,” “lower,” “above,” “upper,” “over,” “higher,” “side” (e.g., as in “sidewall”), and the like, may be used herein for descriptive purposes, and, thereby, to describe one elements relationship to another element(s) as illustrated in the drawings. Spatially relative terms are intended to encompass different orientations of an apparatus in use, operation, and/or manufacture in addition to the orientation depicted in the drawings. For example, if the apparatus in the drawings is turned over, elements described as “below” or “beneath” other elements or features would then be oriented “above” the other elements or features. Thus, the exemplary term “below” can encompass both an orientation of above and below. Furthermore, the apparatus may be otherwise oriented (e.g., rotated 90 degrees or at other orientations), and, as such, the spatially relative descriptors used herein interpreted accordingly.

The terminology used herein is for the purpose of describing particular embodiments and is not intended to be limiting. As used herein, the singular forms, “a,” “an,” and “the” are intended to include the plural forms as well, unless the context clearly indicates otherwise. Moreover, the terms “comprises,” “comprising,” “includes,” and/or “including,” when used in this specification, specify the presence of stated features, integers, steps, operations, elements, components, and/or groups thereof, but do not preclude the presence or addition of one or more other features, integers, steps, operations, elements, components, and/or groups thereof. It is also noted that, as used herein, the terms “substantially,” “about,” and other similar terms, are used as terms of approximation and not as terms of degree, and, as such, are utilized to account for inherent deviations in measured, calculated, and/or provided values that would be recognized by one of ordinary skill in the art.

Unless otherwise defined, all terms (including technical and scientific terms) used herein have the same meaning as commonly understood by one of ordinary skill in the art to which this disclosure is a part. Terms, such as those defined in commonly used dictionaries, should be interpreted as having a meaning that is consistent with their meaning in the context of the relevant art and should not be interpreted in an idealized or overly formal sense, unless expressly so defined herein.

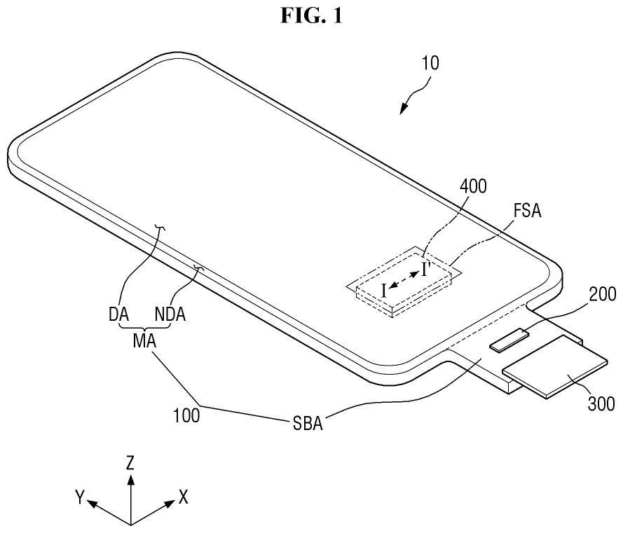

FIG. 1 is a perspective view of an embodiment of a display device 10 constructed according to the principles of the invention.

Referring to FIG. 1, the display device 10 is a device for displaying moving images or still images. The display device 10 may be used as a display screen in portable electronic devices such as mobile phones, smartphones, tablet personal computers (PCs), smart watches, watch phones, mobile communication terminals, electronic notebooks, electronic books, portable multimedia players (PMPs), navigation devices and ultra-mobile PCs (UMPCs), as well as in various products such as televisions, notebook computers, monitors, billboards and the Internet of things (IoT).

The display device 10 may be an organic light emitting display device using organic light emitting diodes, a quantum dot light emitting display device including quantum dot light emitting layers, an inorganic light emitting display device including inorganic semiconductors, a micro light emitting diode display device using micro light emitting diodes or other known display device. Although a case where the display device 10 is an organic light emitting display device is mainly described below, the embodiments are not limited thereto.

The display device 10 includes a display panel 100, a display driving circuit 200, a circuit board 300, and a fingerprint sensor 400.

The display panel 100 may be shaped like a generally rectangular plane having short sides in a first direction (e.g., X-axis direction) and long sides in a second direction (e.g., Y-axis direction) intersecting the first direction. Each corner where a short side extending in the first direction meets a long side extending in the second direction may be rounded to have a predetermined curvature or may be right-angled. The planar shape of the display device 10 is not limited to the rectangular shape, but may also be another generally polygonal shape, a circular shape, or an oval shape. The display panel 100 may be formed substantially flat, but the embodiments are not limited thereto. For example, the display panel 100 may include a curved part which is formed at left and right ends and has a constant or varying curvature. In addition, the display panel 100 may be formed flexibly so that it can be curved, bent, folded, or rolled.

The display panel 100 may include a main area MA and a sub area SBA.

The main area MA may include a display area DA displaying an image and a non-display area NDA located around the display area DA. The display area DA may include display pixels displaying an image. The non-display area NDA may be defined as an area extending from the outside of the display area DA to edges of the display panel 100.

The display area DA may include a fingerprint sensing area FSA. The fingerprint sensing area FSA indicates an area where the fingerprint sensor 400 is disposed. The fingerprint sensing area FSA may be a part of the display area DA as illustrated in FIG. 1, but the embodiments are not limited thereto. The fingerprint sensing area FSA may also be the entire display area DA and substantially the same as the display area DA.

The sub area SBA may protrude from a side of the main area MA in the second direction. The length of the sub area SBA in the first direction may be smaller than the length of the main area MA in the first direction, and the length of the sub area SBA in the second direction may be smaller than the length of the main area MA in the second direction, but the embodiments are not limited thereto.

Although the sub area SBA is unfolded in FIG. 1, it may also be bent, in which case the sub area SBA may be disposed on a lower surface of the display panel 100. When the sub area SBA is bent, it may overlap the main area MA in a thickness direction (e.g., Z-axis direction). The display driving circuit 200 may be disposed in the sub area SBA.

The display driving circuit 200 may generate signals and voltages for driving the display panel 100. The display driving circuit 200 may be formed as an integrated circuit and attached onto the display panel 100 using a chip-on-glass (COG) method, a chip-on-plastic (COP) method, or an ultrasonic bonding method. However, the embodiments are not limited thereto. For example, the display driving circuit 200 may also be attached onto the circuit board 300 using a chip-on-film (COF) method.

The circuit board 300 may be attached to an end of the sub area SBA of the display panel 100 using an anisotropic conductive film. Therefore, the circuit board 300 may be electrically connected to the display panel 100 and the display driving circuit 200. The display panel 100 and the display driving circuit 200 may receive digital video data, timing signals, and driving voltages through the circuit board 300. The circuit board 300 may be a flexible printed circuit board, a printed circuit board, or a flexible film such as a chip-on-film.

The fingerprint sensor 400 may be disposed on the lower surface of the display panel 100. The fingerprint sensor 400 may be attached to the lower surface of the display panel 100 using a transparent adhesive member. For example, the transparent adhesive member may be a transparent adhesive film such as an optically clear adhesive (OCA) film or a transparent adhesive resin such as an optically clear resin (OCR).

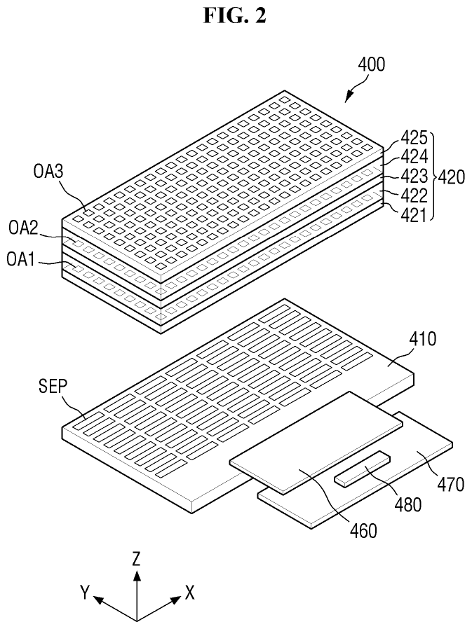

FIG. 2 is an exploded perspective view of an embodiment of the fingerprint sensor 400 of FIG. 1.

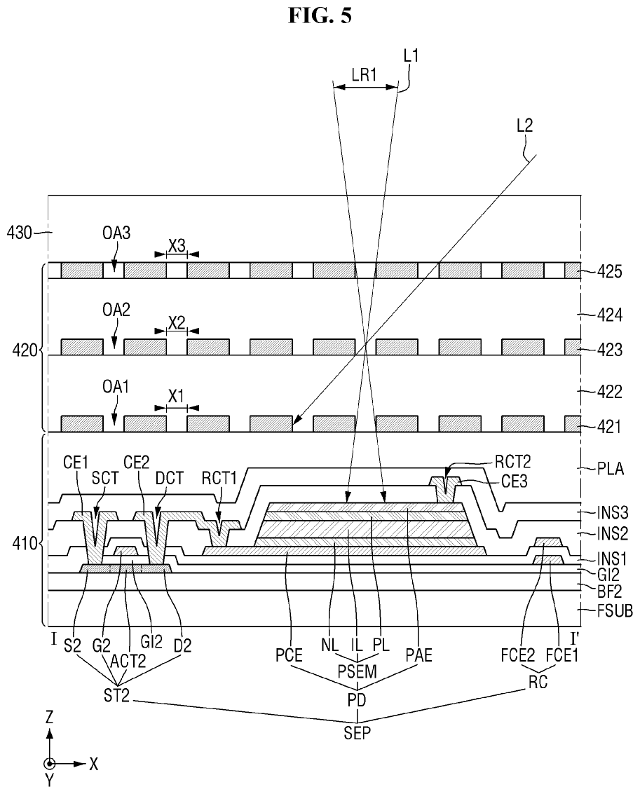

Referring to FIG. 2, the fingerprint sensor 400 may include a light sensor, which may be in the form of a light sensing layer 410, and a light guide such as a collimator, which may be in the form of a light guide layer 420. The light sensing layer 410 may include sensor pixels SEP arranged in the first direction (e.g., X-axis direction) and the second direction (e.g., Y-axis direction). Each of the sensor pixels SEP may include a light sensing element through which a sensing current flows according to incident light, at least one transistor connected to the light sensing element, and at least one capacitor connected to the light sensing element or the transistor. The light sensing element may be a photodiode or a phototransistor. The sensor pixels SEP will be described later with reference to FIG. 5.

The light guide layer 420 is disposed on the sensor pixels SEP of the light sensing layer 410. The light guide layer 420 to guide incident light to the sensor pixels SEP. The light guide layer 420 may include a first light blocking member, which may be in the form of a first light blocking layer 421, a first light transmitting member, which may be in the form of a first transmitting layer 422, a second light blocking member, which may be in the form of a first light blocking layer 423, a second light transmitting member, which may be in the form of a first transmitting layer 424, and a third light blocking member, which may be in the form of a first light blocking layer 425.

The first light blocking layer 421 includes first openings OA1 arranged in the first direction and the second direction. The first light blocking layer 421 includes a light blocking material (e.g., a metal material), and the first openings OA1 may be areas that transmit light.

The first light transmitting layer 422 that transmits light is disposed on the first light blocking layer 421. The first light transmitting layer 422 may be an organic layer.

The second light blocking layer 423 is disposed on the first light transmitting layer 422. The second light blocking layer 423 includes second openings OA2 arranged in the first direction and the second direction. The second light blocking layer 423 includes a light blocking material, and the second openings OA2 may be areas that transmit light.

The second light transmitting layer 423 that transmits light is disposed on the second light blocking layer 423. The second light transmitting layer 424 may be an organic layer.

The third light blocking layer 425 is disposed on the second light transmitting layer 424. The third light blocking layer 425 includes third openings OA3 arranged in the first direction and the second direction. The third light blocking layer 425 includes a light blocking material, and the third openings OA3 may be areas that transmit light.

The first openings OA1, the second openings OA2, and the third openings OA3 may overlap in a third direction (e.g., Z-axis direction). Therefore, light that passes through the first openings OA1, the second openings OA2, and the third openings OA3 may be incident on the sensor pixels SEP of the light sensing layer 410.

Each of the first openings OA1, the second openings OA2, and the third openings OA3 may have a generally quadrangular planar shape as illustrated in FIG. 2, but the embodiments are not limited thereto. For example, each of the first openings OA1, the second openings OA2, and the third openings OA3 may also have a circular shape, an oval shape, or another polygonal shape other than the quadrangular shape in a plan view.

A flexible film 460 may be disposed on the light sensing layer 410 not covered by the light guide layer 420. The flexible film 460 may be attached to an upper surface of the light sensing layer 410 using a conductive adhesive member such as an anisotropic conductive film. Therefore, the flexible film 460 may be electrically connected to the sensor pixels SEP of the light sensing layer 410.

A sensor circuit board 470 may be disposed on the flexible film 460. The sensor circuit board 470 may be attached to a lower surface or an upper surface of the flexible film 460 using a conductive adhesive member such as an anisotropic conductive film. Therefore, the sensor circuit board 470 may be electrically connected to the flexible film 460. The sensor circuit board 470 may be a flexible printed circuit board, a printed circuit board, or a flexible printed circuit cable.

A sensor driving circuit 480 may be disposed on the sensor circuit board 470 as shown in FIG. 2. Alternatively, the sensor driving circuit 480 may be disposed on the flexible film 460. The sensor driving circuit 480 may be attached to the upper surface or the lower surface of the flexible film 460 using a conductive adhesive member such as an anisotropic conductive film. Therefore, the sensor driving circuit 480 may be electrically connected to the flexible film 460. The sensor driving circuit 480 may be an integrated circuit.

Since the sensor driving circuit 480 is electrically connected to the sensor pixels SEP of the light sensing layer 410 through the flexible film 460, it may receive sensing voltages of the sensor pixels SEP. The sensor driving circuit 480 may detect a fingerprint pattern of a finger according to the sensing voltages of the sensor pixels SEP.

As illustrated in FIG. 2, the light guide layer 420 includes the first light blocking layer 421 having the first openings OA1, the second light blocking layer 423 having the second openings OA2, and the third light blocking layer 425 having the third openings OA3. For example, each of the first, second and third light blocking layers 421, 423 and 425 may include a metal material such as molybdenum (Mo), aluminum (Al), chromium (Cr), gold (Au), titanium (Ti), nickel (Ni), neodymium (Nd), or copper (Cu). Therefore, since the sensor pixels SEP of the light sensing layer 410 detect light that passes through the first openings OA1, the second openings OA2, and the third openings OA3, unwanted (ambient) light can be prevented from entering the sensor pixels SEP of the light sensing layer 410.

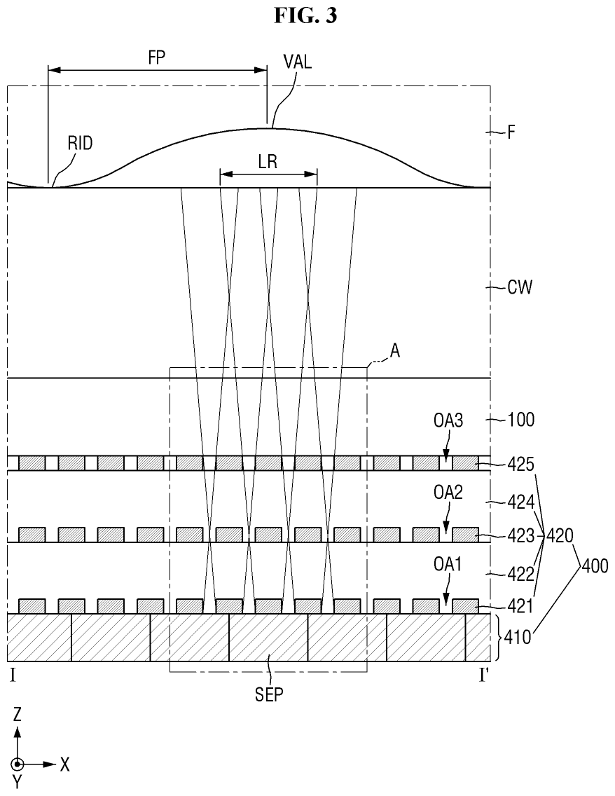

FIG. 3 is a cross-sectional view of an embodiment of the display panel 100 and the fingerprint sensor 400 taken along line I-I′ of FIG. 1. In FIG. 3, a case where a user places a finger F on the display device 10 for fingerprint recognition is illustrated.

Referring to FIG. 3, the display device 10 further includes a cover window CW disposed on an upper surface of the display panel 100. The cover window CW may be disposed on the display panel 100 to cover the upper surface of the display panel 100. The cover window CW may serve to protect the upper surface of the display panel 100. The cover window CW may be attached to the upper surface of the display panel 100 using a transparent adhesive member.

The cover window CW may be made of a transparent material and may be glass or plastic. For example, when the cover window CW is glass, it may be ultra-thin glass (UTG) having a thickness of about 0.1 mm or less. When the cover window CW is plastic, it may include a transparent polyimide film.

The fingerprint sensor 400 may be disposed on the lower surface of the display panel 100. The fingerprint sensor 400 may be attached to the lower surface of the display panel 100 using a transparent adhesive member.

The fingerprint sensor 400 may include the light sensing layer 410 including the sensor pixels SEP and the light guide layer 420 for blocking ambient light from entering the sensor pixels SEP. Each of the sensor pixels SEP may overlap the first openings OA1, the second openings OA2, and the third openings OA3 of the light guide layer 420 in the third direction (Z-axis direction).

Each of the first openings OA1, the second openings OA2, and the third openings OA3 of the light guide layer 420 may be a passage through which light reflected by a ridge RID and a valley VAL of a fingerprint of the finger F is incident. Specifically, when the user's finger F touches the cover window CW, light output from the display panel 100 may be reflected by the ridge RID and the valley VAL of the fingerprint of the finger F. The light reflected by the finger F may be incident on the sensor pixels SEP of the light sensing layer 410 through the display panel 100 and the first openings OA1, the second openings OA2 and the third openings OA3 of the light guide layer 420.

A range LR of light incident on each sensor pixel SEP through the first openings OA1, the second opening OA2, and the third openings OA3 of the light guide layer 420 may be smaller than a distance FP between the ridge RID and the valley VAL of the fingerprint of the finger F. For example, the distance FP between the ridge RID and the valley VAL of the fingerprint of the finger F may be about 500 μm. Therefore, a sensing current flowing through a light sensing element of each sensor pixel SEP may vary according to whether incident light is light reflected by the ridge RID of the fingerprint of the finger F or light reflected by the valley VAL of the fingerprint of the finger F. Accordingly, a sensing voltage output from each sensor pixel SEP may vary according to whether the incident light is the light reflected by the ridge RID of the fingerprint of the finger F or the light reflected by the valley VAL of the fingerprint of the finger F. Therefore, the sensor driving circuit 480 may detect a fingerprint pattern of the finger F according to the sensing voltages of the sensor pixels SEP.

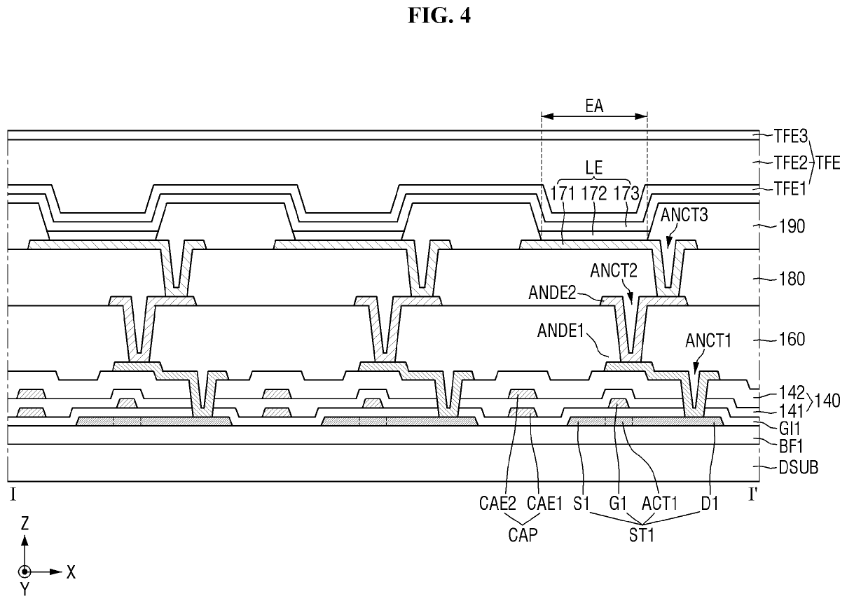

FIG. 4 is an enlarged cross-sectional view of an embodiment of the display panel 100 in area A of FIG. 3 in detail.

Referring to FIG. 4, the display panel may include display pixels displaying an image. Each of the display pixels may include a first thin-film transistor ST1 and a light emitting element layer EML.

A first buffer layer BF1 may be disposed on a display substrate DSUB.

The display substrate DSUB may be made of an insulating material such as polymer resin. For example, the display substrate DSUB may include polyimide. The display substrate DSUB may be a flexible substrate that can be bent, folded, rolled, and the like.

The first buffer layer BF1 is a layer for protecting the first thin-film transistor ST and light emitting layers 172 of a light emitting element layer EML from moisture introduced through the display substrate DSUB which is vulnerable to moisture penetration. The first buffer layer BF1 may be composed of a plurality of inorganic layers stacked alternately. For example, the first buffer layer BF1 may be a multilayer in which one or more inorganic layers selected from a silicon nitride layer, a silicon oxynitride layer, a silicon oxide layer, a titanium oxide layer, and an aluminum oxide layer are alternately stacked.

A first active layer ACT1, a first source electrode S1, and a first drain electrode D1 of each of the first thin-film transistors ST1 may be disposed on the first buffer layer BF1. The first active layer ACT1 includes polycrystalline silicon, monocrystalline silicon, low-temperature polycrystalline silicon, amorphous silicon, or an oxide semiconductor. The first source electrode S1 and the first drain electrode D1 may be formed to have conductivity by doping a silicon semiconductor or an oxide semiconductor with ions or impurities. The first active layer ACT1 may overlap a first gate electrode G1 in the third direction (e.g., Z-axis direction) which is the thickness direction of the display substrate DSUB, and the first source electrode S1 and the first drain electrode D1 may not overlap the first gate electrode G1 in the third direction.

A first gate insulating layer GI1 may be disposed on the first active layer ACT1. The first gate insulating layer GI1 may be an inorganic layer, for example, a silicon nitride layer, a silicon oxynitride layer, a silicon oxide layer, a titanium oxide layer, or an aluminum oxide layer.

The first gate electrode G1 of each of the first thin-film transistors ST1 and a first capacitor electrode CAE1 may be disposed on the first gate insulating layer GI1. The first gate electrode G1 may overlap the first active layer ACT1 in the third direction. The first capacitor electrode CAE1 may overlap a second capacitor electrode CAE2 in the third direction. The first gate electrode G1 may be a single layer or a multilayer made of any one or more of molybdenum (Mo), aluminum (Al), chromium (Cr), gold (Au), titanium (Ti), nickel (Ni), neodymium (Ne), copper (Cu), and alloys of the same.

A first interlayer insulating film 141 may be disposed on the first gate electrodes G1 and the first capacitor electrode CAE1. The first interlayer insulating film 141 may be an inorganic layer, for example, a silicon nitride layer, a silicon oxynitride layer, a silicon oxide layer, a titanium oxide layer, or an aluminum oxide layer.

The second capacitor electrode CAE2 may be disposed on the first interlayer insulating film 141. Since the first interlayer insulating film 141 has a predetermined dielectric constant, the first capacitor electrode CAE1, the second capacitor electrode CAE2, and the first interlayer insulating film 141 disposed between the first capacitor electrode CAE1 and the second capacitor electrode CAE2 may form capacitor CAP. the second capacitor electrode CAE2 may be a single layer or a multilayer made of any one or more of molybdenum (Mo), aluminum (Al), chromium (Cr), gold (Au), titanium (Ti), nickel (Ni), neodymium (Ne), copper (Cu), and alloys of the same.

A second interlayer insulating film 142 may be disposed on the second capacitor electrodes CAE2. The second interlayer insulating film 142 may be an inorganic layer, for example, a silicon nitride layer, a silicon oxynitride layer, a silicon oxide layer, a titanium oxide layer, or an aluminum oxide layer. The second interlayer insulating film 142 may include a plurality of inorganic layers.

First anode connection electrodes ANDE1 may be disposed on the second interlayer insulating film 142. Each of the first anode connection electrodes ANDE1 may be connected to the first drain electrode D1 of a first thin-film transistor ST1 through a first anode contact hole ANCT1 penetrating the first interlayer insulating film 141 and the second interlayer insulating film 142 to expose the first drain electrode D1 of the first thin-film transistor ST1. Each of the first anode connection electrodes ANDE1 may be a single layer or a multilayer made of any one or more of molybdenum (Mo), aluminum (Al), chromium (Cr), gold (Au), titanium (Ti), nickel (Ni), neodymium (Nd), copper (Cu), and alloys of the same.

A first organic layer 160 for planarization may be disposed on the first anode connection electrodes ANDE1. The first organic layer 160 may be an organic layer such as acryl resin, epoxy resin, phenolic resin, polyamide resin, or polyimide resin.

Second anode connection electrodes ANDE2 may be disposed on the first organic layer 160. Each of the second anode connection electrodes ANDE2 may be connected to a first anode connection electrode ANDE1 through a second anode contact hole ANCT2 penetrating the first organic layer 160 to expose the first anode connection electrode ANDE1. Each of the second anode connection electrodes ANDE2 may be a single layer or a multilayer made of any one or more of molybdenum (Mo), aluminum (Al), chromium (Cr), gold (Au), titanium (Ti), nickel (Ni), neodymium (Nd), copper (Cu), and alloys of the same.

A second organic layer 180 may be disposed on the second anode connection electrodes ANDE2. The second organic layer 180 may be an organic layer such as acryl resin, epoxy resin, phenolic resin, polyamide resin, or polyimide resin.

In FIG. 4, each of the first thin-film transistors ST1 is formed as a top-gate type in which the first gate electrode G1 is located above the first active layer ACT1. However, it should be noted that the embodiments are not limited thereto. For example, each of the first thin-film transistors ST1 may also be formed as a bottom-gate type in which the first gate electrode G1 is located under the first active layer ACT1 or a double-gate type in which the first gate electrode G1 is located both above and under the first active layer ACT1.

The light emitting element layer EML and a bank 190 may be disposed on the second organic layer 180. The light emitting element layer EML includes a first light emitting electrode 171, the light emitting layer 172, and a second light emitting electrode 173.

The first light emitting electrode 171 may be formed on the second organic layer 180. The first light emitting electrode 171 may be connected to each of the second anode connection electrodes ANDE2 through a third anode contact hole ANCT3 penetrating the second organic layer 180 to expose the second anode connection electrode ANDE2.

In a top emission structure in which light is emitted in a direction from the light emitting layer 172 toward the second light emitting electrode 173, the first light emitting electrode 171 may be made of a metal material having high reflectivity, such as a stacked structure (Ti/Al/Ti) of aluminum and titanium, a stacked structure (ITO/Al/ITO) of aluminum and indium tin oxide, an APC alloy, or a stacked structure (ITO/APC/ITO) of an APC alloy and indium tin oxide. The APC alloy is an alloy of silver (Ag), palladium (Pd), and copper (Cu).

The bank 190 may be formed on the second organic layer 180 to separate the first light emitting electrodes 171 so as to define emission area EA. The bank 190 may be formed to cover edges of the first light emitting electrodes 171. The bank 190 may be an organic layer such as acryl resin, epoxy resin, phenolic resin, polyamide resin, or polyimide resin.

Te emission area EA is an area in which the first light emitting electrode 171, the light emitting layer 172 and the second light emitting electrode 173 are sequentially stacked so that holes from the first light emitting electrode 171 and electrons from the second light emitting electrode 173 combine together in the light emitting layer 172 to emit light.

The light emitting layer 172 is formed on the first light emitting electrode 171 and the bank 190. The light emitting layer 172 may include an organic material to emit light of a predetermined color. For example, the light emitting layer 172 may include a hole transporting layer, an organic material layer, and an electron transporting layer.

The second light emitting electrode 173 is formed on the light emitting layer 172. The second light emitting electrode 173 may be formed to cover the light emitting layer 172. The second light emitting electrode 173 may be a common layer common to all emission areas EA. A capping layer may be formed on the second light emitting electrode 173.

In the top emission structure, the second light emitting electrode 173 may be made of a transparent conductive oxide (TCO) capable of transmitting light, such as indium tin oxide (ITO) or indium zinc oxide (IZO), or a semi-transmissive conductive material such as magnesium (Mg), silver (Ag) or an alloy of Mg and Ag. When the second light emitting electrode 173 is made of a semi-transmissive conductive material, light output efficiency may be increased by a microcavity.

An encapsulation layer TFE may be disposed on the second light emitting electrode 173. The encapsulation layer TFE includes at least one inorganic layer to prevent oxygen or moisture from penetrating into the light emitting element layer EML. In addition, the encapsulation layer TFE includes at least one organic layer to protect the light emitting element layer EML from foreign substances such as dust. For example, the encapsulation layer TFE includes a first inorganic layer TFE1, an organic layer TFE2, and a second inorganic layer TFE3.

The first inorganic layer TFE1 may be disposed on the second light emitting electrode 173, the organic layer TFE2 may be disposed on the first inorganic layer TFE1, and the second inorganic layer TFE3 may be disposed on the organic layer TFE2. Each of the first inorganic layer TFE1 and the second inorganic layer TFE3 may be a multilayer in which one or more inorganic layers selected from a silicon nitride layer, a silicon oxynitride layer, a silicon oxide layer, a titanium oxide layer, and an aluminum oxide layer are alternately stacked. The organic layer TFE2 may be a monomer.

FIG. 5 is an enlarged cross-sectional view of a first embodiment of the fingerprint sensor 400 in area A of FIG. 3 in detail.

Referring to FIG. 5, the fingerprint sensor 400 may include the light sensing layer 410 and the light guide layer 420 disposed on the light sensing layer 410.

The light sensing layer 410 may include the sensor pixels SEP that detect light. Each of the sensor pixels SEP may include a second thin-film transistor ST2, a light sensing element PD, and a sensing capacitor RC.

A second buffer layer BF2 may be disposed on a fingerprint sensor substrate FSUB. The fingerprint sensor substrate FSUB may be made of an insulating material such as polymer resin. For example, the fingerprint sensor substrate FSUB may include polyimide. The fingerprint sensor substrate FSUB may be a flexible substrate that can be bent, folded, rolled, and the like.

The second buffer layer BF2 is a layer for protecting the second thin-film transistor ST2 and the light sensing element PD of the light sensing layer 410 from moisture introduced through the fingerprint sensor substrate FSUB which is vulnerable to moisture penetration. The second buffer layer BF2 may be composed of a plurality of inorganic layers stacked alternately. For example, the second buffer layer BF2 may be a multilayer in which one or more inorganic layers selected from a silicon nitride layer, a silicon oxynitride layer, a silicon oxide layer, a titanium oxide layer, and an aluminum oxide layer are alternately stacked.

A second active layer ACT2, a second source electrode S2, and a second drain electrode D2 of the second thin-film transistor ST2 may be disposed on the second buffer layer BF2. The second active layer ACT2 includes polycrystalline silicon, monocrystalline silicon, low-temperature polycrystalline silicon, amorphous silicon, or an oxide semiconductor. The second source electrode S2 and the second drain electrode D2 may be formed to have conductivity by doping a silicon semiconductor or an oxide semiconductor with ions or impurities. The second active layer ACT2 may overlap a second gate electrode G2 in the third direction (e.g., Z-axis direction) which is the thickness direction of the fingerprint sensor substrate FSUB, and the second source electrode S2 and the second drain electrode D2 may not overlap the second gate electrode G2 in the third direction.

A second gate insulating layer G12 may be disposed on the second active layer ACT2. The second gate insulating layer G12 may be an inorganic layer, for example, a silicon nitride layer, a silicon oxynitride layer, a silicon oxide layer, a titanium oxide layer, or an aluminum oxide layer.

The second gate electrode G2 of the second thin-film transistor ST2 and a first fingerprint capacitor electrode FCE1 may be disposed on the second gate insulating layer GI2. The second gate electrode G2 of the second thin-film transistor ST2 may overlap the second active layer ACT2 in the third direction. The first fingerprint capacitor electrode FCE1 may overlap a second fingerprint capacitor electrode FCE2 in the third direction. Each of the second gate electrode G2 and the first fingerprint capacitor electrode FCE1 may be a single layer or a multilayer made of any one or more of molybdenum (Mo), aluminum (Al), chromium (Cr), gold (Au), titanium (Ti), nickel (Ni), neodymium (Ne), copper (Cu), and alloys of the same.

A first insulating layer INS1 may be disposed on the second gate electrode G2 and the first fingerprint capacitor electrode FCE1. The first insulating layer INS1 may be an inorganic layer, for example, a silicon nitride layer, a silicon oxynitride layer, a silicon oxide layer, a titanium oxide layer, or an aluminum oxide layer. The first insulating layer INS1 may include a plurality of inorganic layers.

The light sensing element PD and the second fingerprint capacitor electrode FCE2 may be disposed on the first insulating layer INS1. The second fingerprint capacitor electrode FCE2 may overlap the first fingerprint capacitor electrode FCE1 in the third direction. Since the first insulating layer INS1 has a predetermined dielectric constant, the first fingerprint capacitor electrode FCE1, the second fingerprint capacitor electrode FCE2, and the first insulating layer INS1 disposed between the first fingerprint capacitor electrode FCE1 and the second fingerprint capacitor electrode FCE2 may form the sensing capacitor RC.

The light sensing element PD may be formed as a photodiode as illustrated in FIG. 5. However, the embodiments are not limited thereto. The light sensing element PD may also be formed as a phototransistor. The light sensing element PD may include a first sensing electrode PCE, a sensing semiconductor layer PSEM, and a second sensing electrode PAE. The first sensing electrode PCE may be a cathode, and the second sensing electrode PAE may be an anode.

The first sensing electrode PCE may be disposed on the first insulating layer INS1. The first sensing electrode PCE may be made of the same material as the second fingerprint capacitor electrode FCE2. Each of the first sensing electrode PCE and the second fingerprint capacitor electrode FCE2 may be a single layer of molybdenum (Mo), titanium (Ti), copper (Cu) or aluminum (Al) or may have a stacked structure (Ti/Al/Ti) of aluminum and titanium, a stacked structure (ITO/Al/ITO) of aluminum and indium tin oxide, an APC alloy, or a stacked structure (ITO/APC/ITO) of an APC alloy and indium tin oxide.

The sensing semiconductor layer PSEM may be disposed on the first sensing electrode PCE. The sensing semiconductor layer PSEM may be formed in a PIN structure in which a P-type semiconductor layer PL, an I-type semiconductor layer IL, and an N-type semiconductor layer NL are sequentially stacked. When the sensing semiconductor layer PSEM is formed in the PIN structure, the I-type semiconductor layer IL is depleted by the P-type semiconductor layer PL and the N-type semiconductor layer NL. Accordingly, an electric field is generated in the I-type semiconductor layer IL, and holes and electrons generated by sunlight are drifted by the electric field. Therefore, the holes may be collected to the second sensing electrode PAE through the P-type semiconductor layer PL, and the electrons may be collected to the first sensing electrode PCE through the N-type semiconductor layer NL.

The P-type semiconductor layer PL may be disposed close to a surface on which external light is incident, and the N-type semiconductor layer NL may be disposed far away from the surface on which the external light is incident. Since drift mobility of holes is low compared with drift mobility of electrons, the P-type semiconductor layer PL may be formed close to the incident surface of the external light in order to maximize collection efficiency due to incident light.

The N-type semiconductor layer NL may be disposed on the first sensing electrode PCE, the I-type semiconductor layer IL may be disposed on the N-type semiconductor layer NL, and the P-type semiconductor layer PL may be disposed on the I-type semiconductor layer IL. In this case, the P-type semiconductor layer PL may be formed by doping amorphous silicon (a-Si:H) with a P-type dopant. The I-type semiconductor layer IL may be made of amorphous silicon germanium (a-SiGe:H) or amorphous silicon carbide (a-SiC:H). The N-type semiconductor layer NL may be formed by doping amorphous silicon germanium (a-SiGe:H) or amorphous silicon carbide (a-SiC:H) with an N-type dopant. The P-type semiconductor layer PL and the N-type semiconductor layer NL may be formed to a thickness of about 500 Å, and the I-type semiconductor layer IL may be formed to a thickness of about 5,000 to about 10,000 Å.

Alternatively, the N-type semiconductor layer NL may be disposed on the first sensing electrode PCE, the I-type semiconductor layer IL may be omitted, and the P-type semiconductor layer PL may be disposed on the N-type semiconductor layer NL. In this case, the P-type semiconductor layer PL may be formed by doping amorphous silicon (a-Si:H) with a P-type dopant. The N-type semiconductor layer NL may be formed by doping amorphous silicon germanium (a-SiGe:H) or amorphous silicon carbide (a-SiC:H) with an N-type dopant. The P-type semiconductor layer PL and the N-type semiconductor layer NL may be formed to a thickness of about 500 Å.

In addition, an upper surface or a lower surface of at least any one of the first sensing electrode PCE, the P-type semiconductor layer PL, the I-type semiconductor layer IL, the N-type semiconductor layer NL, and the second sensing electrode PAE may be formed to have an uneven structure through a texturing process in order to increase an absorption rate of external light. The texturing process is a process of forming a material surface into an uneven structure and processing the material surface into a shape such as a fabric surface. The texturing process may be performed through an etching process using photolithography, an anisotropic etching process using a chemical solution, or a groove forming process using mechanical scribing.

The second sensing electrode PAE may be disposed on the P-type semiconductor layer PL. The second sensing electrode PAE may be made of a transparent conductive material (TCO) capable of transmitting light, such as indium tin oxide (ITO) or indium zinc oxide (IZO).

A second insulating layer INS2 may be disposed on the light sensing element PD and the second fingerprint capacitor electrode FCE2. The second insulating layer INS2 may be an inorganic layer, for example, a silicon nitride layer, a silicon oxynitride layer, a silicon oxide layer, a titanium oxide layer, or an aluminum oxide layer. The second insulating layer INS2 may include a plurality of inorganic layers.

A first connection electrode CE1, a second connection electrode CE2, and a third connection electrode CE3 may be disposed on the second insulating layer INS2.

The first connection electrode CE1 may be connected to the second source electrode S2 of the second thin-film transistor ST2 through a source contact hole SCT penetrating the first insulating layer INS1 and the second insulating layer INS2 to expose the second source electrode S2 of the second thin-film transistor ST2.

The second connection electrode CE2 may be connected to the second drain electrode D2 of the second thin-film transistor ST2 through a drain contact hole DCT penetrating the first insulating layer INS1 and the second insulating layer INS2 to expose the second drain electrode D2 of the second thin-film transistor ST2. The second connection electrode CE2 may be connected to the first sensing electrode PCE through a first sensing contact hole RCT1 penetrating the second insulating layer INS2 to expose the first sensing electrode PCE. Therefore, the second drain electrode D2 of the second thin-film transistor ST2 and the first sensing electrode PCE of the light sensing element PD may be connected by the second connection electrode CE2.

The third connection electrode CE3 may be connected to the second sensing electrode PAE through a second sensing contact hole RCT2 penetrating the second insulating layer INS2 to expose the second sensing electrode PAE.

Each of the first connection electrode CE1, the second connection electrode CE2, and the third connection electrode CE3 may be a single layer or a multilayer made of any one or more of molybdenum (Mo), aluminum (Al), chromium (Cr), gold (Au), titanium (Ti), nickel (Ni), neodymium (Nd), copper (Cu), and alloys of the same.

A third insulating layer INS3 may be disposed on the first connection electrode CE1, the second connection electrode CE2, and the third connection electrode CE3. The third insulating layer INS3 may be an inorganic layer, for example, a silicon nitride layer, a silicon oxynitride layer, a silicon oxide layer, a titanium oxide layer, or an aluminum oxide layer. The third insulating layer INS3 may include a plurality of inorganic layers. The third insulating layer INS3 can be omitted.

A planarization layer PLA may be disposed on the third insulating layer INS3. The planarization layer PLA may be an organic layer such as acryl resin, epoxy resin, phenolic resin, polyamide resin, or polyimide resin.

The light guide layer 420 may include the first light blocking layer 421, the first light transmitting layer 422, the second light blocking layer 423, the second light transmitting layer 424, and the third light blocking layer 425.

The first light blocking layer 421 may be disposed on the planarization layer PLA of the light sensing layer 410. The first light blocking layer 421 may include the first openings OA1. Lengths of each of the first openings OA1 in the first direction (e.g., X-axis direction) and the second direction (e.g., Y-axis direction) may be substantially equal or different. In addition, the first openings OA1 may be disposed side by side in the first direction and the second direction. That is, the first openings OA1 may be disposed in a matrix. In this case, the distance between the first openings OA1 in the first direction and the distance between the first openings OA1 in the second direction may be substantially equal or different.

The first light blocking layer 421 may include a light blocking material. For example, the first light blocking layer 421 may include a metal material such as molybdenum (Mo), aluminum (Al), chromium (Cr), gold (Au), titanium (Ti), nickel (Ni), neodymium (Nd), or copper (Cu).

The first light transmitting layer 422 may be disposed on the first light blocking layer 421. The first light transmitting layer 422 may fill the first openings OA1 of the first light blocking layer 421. The first light transmitting layer 422 may have a thickness of several to several tens of μm. The first light transmitting layer 422 may be an organic layer such as acryl resin, epoxy resin, phenolic resin, polyamide resin, or polyimide resin.

The second light blocking layer 423 may be disposed on the first light transmitting layer 422. The second light blocking layer 423 may include the second openings OA2 respectively overlapping the first openings OA1 in the third direction (e.g., Z-axis direction) which is the thickness direction of the fingerprint sensor substrate FSUB. Lengths of each of the second openings OA2 in the first direction and the second direction may be substantially equal or different. In addition, the second openings OA2 may be disposed side by side in the first direction and the second direction. That is, the second openings OA2 may be disposed in a matrix. In this case, the distance between the second openings OA2 in the first direction and the distance between the second openings OA2 in the second direction may be substantially equal or different.

The second light blocking layer 423 may include a light blocking material. For example, the second light blocking layer 423 may include a metal material such as molybdenum (Mo), aluminum (Al), chromium (Cr), gold (Au), titanium (Ti), nickel (Ni), neodymium (Nd), or copper (Cu).

The second light transmitting layer 424 may be disposed on the second light blocking layer 423. The second light transmitting layer 424 may fill the second openings OA2 of the second light blocking layer 423. The second light transmitting layer 424 may have a thickness of several to several tens of μm. The second light transmitting layer 424 may be an organic layer such as acryl resin, epoxy resin, phenolic resin, polyamide resin, or polyimide resin.

The third light blocking layer 425 may be disposed on the second light transmitting layer 424. The third light blocking layer 425 may include the third openings OA3 respectively overlapping the first openings OA1 and the second openings OA2 in the third direction. Lengths of each of the third openings OA3 in the first direction and the second direction may be substantially equal or different. In addition, the third openings OA3 may be disposed side by side in the first direction and the second direction. That is, the third openings OA3 may be disposed in a matrix. In this case, the distance between the third openings OA3 in the first direction and the distance between the third openings OA3 in the second direction may be substantially equal or different.

The third light blocking layer 425 may include a light blocking material. For example, the third light blocking layer 425 may include a metal material such as molybdenum (Mo), aluminum (Al), chromium (Cr), gold (Au), titanium (Ti), nickel (Ni), neodymium (Nd), or copper (Cu).

The first openings OA1, the second openings OA2, and the third openings OA3 may overlap each other in the third direction. Therefore, light L1 that passes through the first openings OA1, the second openings OA2, and the third openings OA3 may be incident on the sensor pixels SEP. Light L2 other than the light L1 that passes through the first openings OA1, the second openings OA2, and the third openings OA3 overlapping each other in the third direction is blocked by the first light blocking layer 421, the second light blocking layer 423, and the third light blocking layer 425. Thus, incidence of ambient light on the sensor pixels SEP can be minimized. The ambient light refers to light incident on the sensor pixels SEP after passing through the first openings OA1, the second openings OA2 and the third openings OA3 not overlapping each other in the third direction, such as shown by line L2.

The first openings OA1, the second openings OA2, and the third openings OA3 may have substantially the same size. A length X1 of each first opening OA1 in the first direction, a length X2 of each second opening OA2 in the first direction, and a length X3 of each third opening OA3 in the first direction may be substantially equal. The length of each first opening OA1 in the second direction, the length of each second opening OA2 in the second direction, and the length of each third opening OA3 in the second direction may be substantially equal.

A transparent adhesive member 430 may be disposed on the third light blocking layer 425. The transparent adhesive member 430 may be attached to an upper surface of the light guide layer 420 and the lower surface of the display panel 100.

As illustrated in FIG. 5, the first light blocking layer 421, the second light blocking layer 423, and the third light blocking layer 425 are formed using a metal material. That is, since the first light blocking layer 421, the second light blocking layer 423, and the third light blocking layer 425 are not made of photosensitive resin capable of blocking light, for example, an organic material including an inorganic black pigment such as carbon black or an organic black pigment, equipment contamination does not occur when the first light blocking layer 421, the second light blocking layer 423, and the third light blocking layer 425 of the light guide layer 420 are formed. Therefore, a manufacturing device for forming the second thin-film transistor ST2, the light sensing element PD, and the sensing capacitor RC of each of the sensor pixels SEP of the light sensing layer 410 can also be used as a manufacturing device for forming the light guide layer 420. Thus, the fingerprint sensor 400 including the light guide layer 420 can be manufactured without adding a separate manufacturing device.

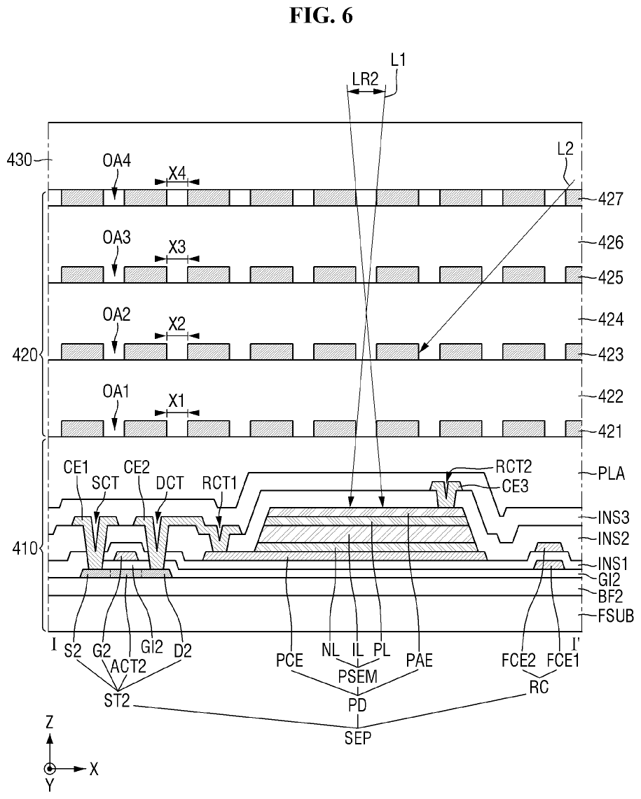

FIG. 6 is an enlarged cross-sectional view of a second embodiment of the fingerprint sensor 400 in area A of FIG. 3 in detail.

The embodiment of FIG. 6 is different from the embodiment of FIG. 5 in that a light guide layer 420 further includes a third light transmitting layer 426 and a fourth light blocking layer 427. In FIG. 6, differences from the embodiment of FIG. 5 will be mainly described.

Referring to FIG. 6, the third light transmitting layer 426 may be disposed on a third light blocking layer 425. The third light transmitting layer 426 may fill third openings OA3 of the third light blocking layer 425. The third light transmitting layer 426 may have a thickness of about several to several tens of μm. The third light transmitting layer 426 may be an organic layer such as acryl resin, epoxy resin, phenolic resin, polyamide resin, or polyimide resin.

The fourth light blocking layer 427 may be disposed on the third light transmitting layer 426. The fourth light blocking layer 427 may include fourth openings OA4 respectively overlapping first openings OA1, second openings OA2, and the third openings OA3 in the third direction.

The first openings OA1, the second openings OA2, the third openings OA3, and the fourth openings OA4 may have substantially the same size. A length X1 of each first opening OA1 in the first direction, a length X2 of each second opening OA2 in the first direction, a length X3 of each third opening OA3 in the first direction, and a length X4 of each fourth opening OA4 in the first direction may be substantially equal. A length of each first opening OA1 in the second direction, a length of each second opening OA2 in the second direction, a length of each third opening OA3 in the second direction, and a length of each fourth opening OA4 in the second direction may be substantially equal.

The lengths of each of the fourth openings OA4 in the first direction and the second direction may be substantially equal or different. In addition, the fourth openings OA4 may be disposed side by side in the first direction and the second direction. That is, the fourth openings OA4 may be disposed in a matrix. In this case, the distance between the fourth openings OA4 in the first direction and the distance between the fourth openings OA4 in the second direction may be substantially equal or different.

The fourth light blocking layer 427 may include a light blocking material. For example, the fourth light blocking layer 427 may include a metal material such as molybdenum (Mo), aluminum (Al), chromium (Cr), gold (Au), titanium (Ti), nickel (Ni), neodymium (Nd), or copper (Cu). Alternatively, the fourth light blocking layer 425 may include an inorganic black pigment such as carbon black or an organic black pigment.

The first light blocking layer 421 having the first openings OA1, the second light blocking layer 423 having the second openings OA2, and the third light blocking layer 425 having the third openings OA3 may be formed using a photolithography process. In the photolithography process, it is difficult to form the lengths of each of the first openings OA1, the second openings OA2, and the third openings OA3 in the first direction and the second direction to be smaller than about 2 μm. Due to the limitations of the photolithography process, the range LR of light incident on a sensor pixel SEP through the openings OA1, OA2 and OA3 as in FIG. 3 may be greater than a distance FP between a ridge RID and a valley VAL of a fingerprint of a finger F. In this case, it is difficult to distinguish whether light incident on the sensor pixel SEP is light reflected by the ridge RID of the fingerprint of the finger F or light reflected by the valley VAL of the fingerprint. Therefore, the accuracy of a fingerprint pattern of the finger F detected through the fingerprint sensor 400 may be lowered.

When the fourth light blocking layer 427 having the fourth openings OA4 is further included as illustrated in FIG. 6, a range LR2 of light incident on a sensor pixel SEP through the openings OA1, OA2, OA3 and OA4 overlapping in the third direction may be smaller than a range LR1 of light incident on a sensor pixel SEP through the openings OA1, OA2 and OA3 overlapping in the third direction as illustrated in FIG. 5. In this case, the range LR2 of light incident on a sensor pixel SEP through the openings OA1, OA2, OA3 and OA4 as in FIG. 6 may be reduced.

Although four light blocking layers 421, 423, 425 and 427 are illustrated in FIG. 6, the number of stacked light blocking layers 421, 423, 425 and 427 is not limited thereto. The number of the stacked light blocking layers 421, 423, 425 and 427 may be appropriately set in consideration of the range of light incident on a sensor pixel SEP through the openings OA1, OA2, OA3 and OA4 and the distance FP between the ridge RD and the valley VAL of the fingerprint of the finger F.

By adjusting the number of the stacked light blocking layers 421, 423, 425 and 427 as in FIG. 6, the range LR2 of light incident on a sensor pixel SEP through the openings OA1, OA2, OA3 and OA4 can be made smaller than the distance FP between the ridge RD and the valley VAL of the fingerprint of the finger F. Therefore, it is possible to prevent the accuracy of the fingerprint pattern of the finger F detected through the fingerprint sensor 400 from being lowered.

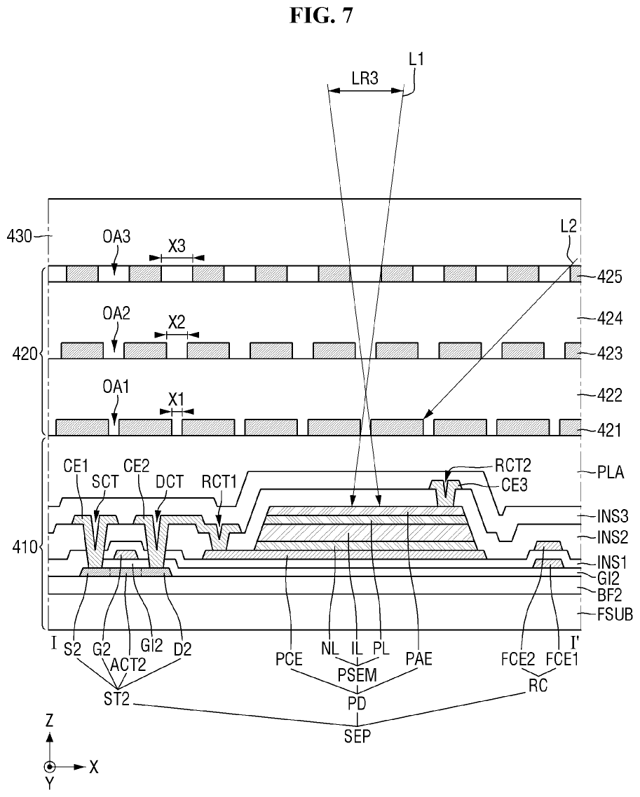

FIG. 7 is an enlarged cross-sectional view of a third embodiment of the fingerprint sensor 400 in area A of FIG. 3 in detail.

The embodiment of FIG. 7 is different from the embodiment of FIG. 5 in that first openings OA1, second openings OA2, and third openings OA3 have different sizes. In FIG. 7, differences from the embodiment of FIG. 5 will be mainly described.

Referring to FIG. 7, the third openings OA3 may be the largest, and the first openings OA1 may be the smallest. That is, the third openings OA3 may be larger than the first openings OA1 and the second openings OA2, and the second openings OA2 may be larger than the first openings OA1.

A length X3 of each third opening OA3 in the first direction may be greater than a length X1 of each first opening OA1 in the first direction and a length X2 of each second opening OA2 in the first direction. The length X2 of each second opening OA2 in the first direction may be greater than the length X1 of each first opening OA1 in the first direction.

The length of each third opening OA3 in the second direction may be greater than the length of each first opening OA1 in the second direction and the length of each second opening OA2 in the second direction. The length of each second opening OA2 in the second direction may be greater than the length of each first opening OA1 in the second direction.

A range LR3 of light incident on a sensor pixel SEP through the openings OA1, OA2 and OA3 overlapping in the third direction as illustrated in FIG. 7 may be greater than the range LR1 of light incident on a sensor pixel SEP through the openings OA1, OA2 and OA3 overlapping in the third direction as illustrated in FIG. 5. Therefore, since a greater amount of light is incident on a sensor pixel SEP, the amount of light incident on the sensor pixel SEP may vary greatly according to whether light incident on the sensor pixel SEP is light reflected by a ridge RID of a fingerprint of a finger F or light reflected by a valley VAL of the fingerprint of the finger F. Accordingly, the ridge RID and the valley VAL of a fingerprint pattern of the finger F detected by the fingerprint sensor 400 may be clear.

However, in FIG. 7, the range LR3 of light incident on a sensor pixel SEP through the openings OA1, OA2 and OA3 may be greater than a distance FP between the ridge RID and the valley VAL of the fingerprint of the finger F. In this case, since it is not clear whether light incident on a sensor pixel SEP is light reflected by the ridge RD of the fingerprint of the finger F or light reflected by the valley VAL of the fingerprint, the accuracy of the fingerprint pattern of the finger F detected through the fingerprint sensor 400 may be lowered.

In FIG. 7, the range LR3 of light incident on a sensor pixel SEP through the openings OA1, OA2 and OA3 depends on the size of each third opening OA3. Therefore, to prevent the accuracy of the fingerprint pattern of the finger F detected through the fingerprint sensor 400 from being lowered, the size of each third opening OA3 may be set such that the range LR3 of light incident on a sensor pixel SEP through the first openings OA1, the second openings OA2, and the third openings OA3 is not greater than the distance FP between the ridge RID and the valley VAL of the fingerprint of the finger F.

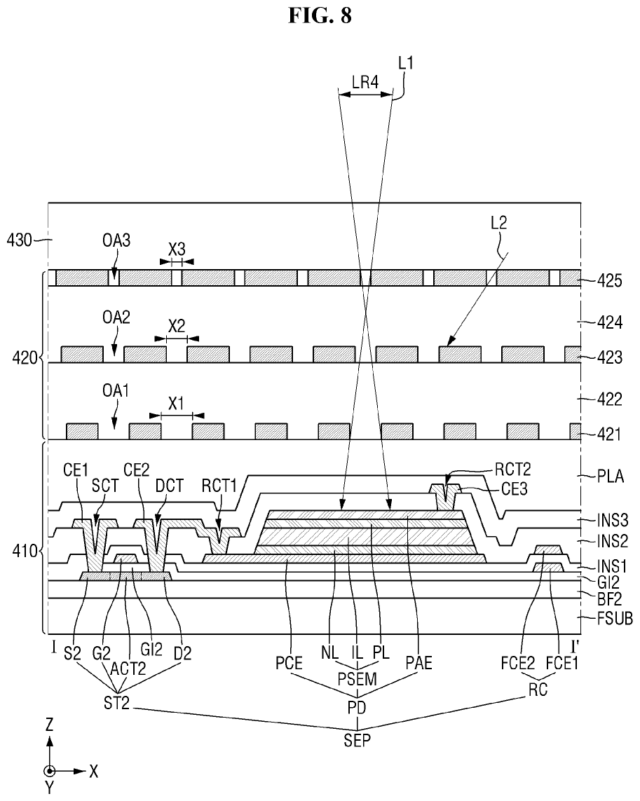

FIG. 8 is an enlarged cross-sectional view of a fourth embodiment of the fingerprint sensor 400 in area A of FIG. 3 in detail.

The embodiment of FIG. 8 is different from the embodiment of FIG. 5 in that first openings OA1, second openings OA2, and third openings OA3 have different sizes. In FIG. 8, differences from the embodiment of FIG. 5 will be mainly described.

Referring to FIG. 8, the first openings OA1 may be the largest, and the third openings OA3 may be the smallest. That is, the first openings OA1 may be larger than the second openings OA2 and the third openings OA3, and the second openings OA2 may be larger than the third openings OA3.

A length X1 of each first opening OA1 in the first direction may be greater than a length X2 of each second opening OA2 in the first direction and a length X3 of each third opening OA3 in the first direction. The length X2 of each second opening OA2 in the first direction may be greater than the length X3 of each third opening OA3 in the first direction.

The length of each first opening OA1 in the second direction may be greater the length of each second opening OA2 in the second direction and the length of each third opening OA3 in the second direction. The length of each second opening OA2 in the second direction may be greater than the length of each third opening OA3 in the second direction.

A range LR4 of light incident on a sensor pixel SEP through the openings OA1, OA2 and OA3 overlapping in the third direction as illustrated in FIG. 8 may be smaller than the range LR1 of light incident on a sensor pixel SEP through the openings OA1, OA2 and OA3 overlapping in the third direction as illustrated in FIG. 5. Therefore, the range LR4 of light incident on a sensor pixel SEP through the first openings OA1, the second openings OA2, and the third openings OA3 may be smaller than a distance FP between a ridge RID and a valley VAL of a fingerprint of a finger F. In addition, since the range LR4 of light incident on the sensor pixel SEP may be located on the ridge RID of the fingerprint of the finger F or the valley VAL of the fingerprint, the accuracy of a fingerprint pattern of the finger F detected through the fingerprint sensor 400 can be further increased.

However, since a smaller amount of light is incident on a sensor pixel SEP, the amount of light incident on the sensor pixel SEP may vary slightly according to whether light incident on the sensor pixel SEP is light reflected by the ridge RID of the fingerprint of the finger F or light reflected by the valley VAL of the fingerprint of the finger F. Since the amount of light incident on a sensor pixel SEP depends on the size of each third opening OA3, the size of each third opening OA3 may be set such that a difference in the amount of light incident on the sensor pixel SEP between when the incident light is light reflected by the ridge RID of the fingerprint of the finger F and when the incident light is light reflected by the valley VAL of the fingerprint of the finger F is not smaller than a predetermined threshold value.

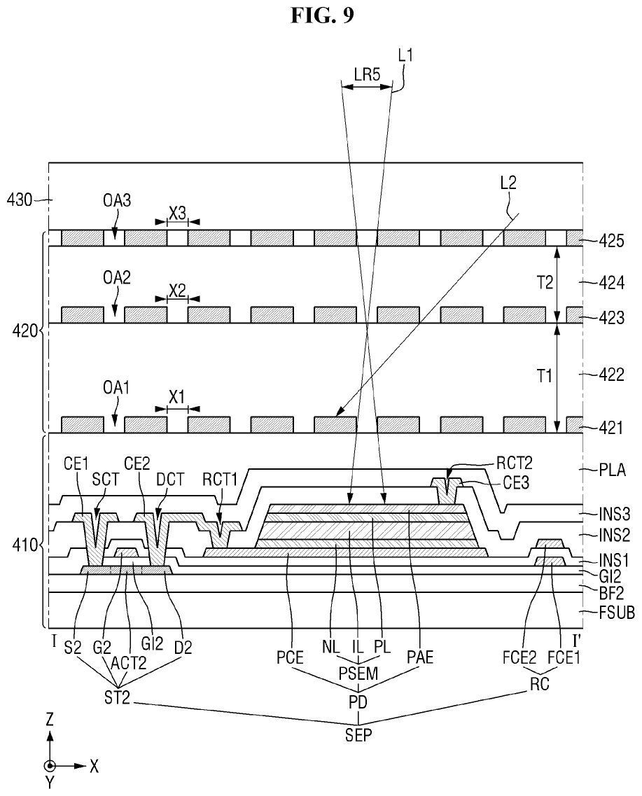

FIG. 9 is an enlarged cross-sectional view of a fifth embodiment of the fingerprint sensor 400 in area A of FIG. 3 in detail.

The embodiment of FIG. 9 is different from the embodiment of FIG. 5 in that a thickness T1 of a first light transmitting layer 422 is greater than a thickness T2 of a second light transmitting layer 424. In FIG. 9, differences from the embodiment of FIG. 5 will be mainly described.

Referring to FIG. 9, when the thickness T1 of the first light transmitting layer 422 is greater than the thickness T2 of the second light transmitting layer 424, a range LR5 of light incident on a sensor pixel SEP through openings OA1, OA2 and OA3 overlapping in the third direction may be smaller than the range LR1 of light incident on a sensor pixel SEP through the openings OA1, OA2 and OA3 overlapping in the third direction as illustrated in FIG. 5. Therefore, the range LR5 of light incident on a sensor pixel SEP through first openings OA1, second openings OA2, and third openings OA3 may be smaller than a distance FP between a ridge RID and a valley VAL of a fingerprint of a finger F. In addition, since the range LR5 of light incident on the sensor pixel SEP may be located on the ridge RID of the fingerprint of the finger F or the valley VAL of the fingerprint, the accuracy of a fingerprint pattern of the finger F detected through the fingerprint sensor 400 can be further increased.

When the thickness T1 of the first light transmitting layer 422 is greater than the thickness T2 of the second light transmitting layer 424, light L2 other than light L1 that passes through the first openings OA1, the second openings OA2, and the third openings OA3 overlapping each other in the third direction may be blocked by a first light blocking layer 421, a second light blocking layer 423, and a third light blocking layer 425. Thus, incidence of ambient light on a sensor pixel SEP can be minimized. The ambient light refers to light incident on a sensor pixel SEP after passing through the first openings OA1, the second openings OA2 and the third openings OA3 not overlapping each other in the third direction (Z-axis direction).

On the other hand, when the thickness T2 of the second light transmitting layer 424 is greater than the thickness T1 of the first light transmitting layer 422, the light L2 other than the light L1 that passes through the first openings OA1, the second openings OA2, and the third openings OA3 overlapping each other in the third direction may be incident on a sensor pixel SEP. That is, the ambient light may not incident on the sensor pixel SEP.

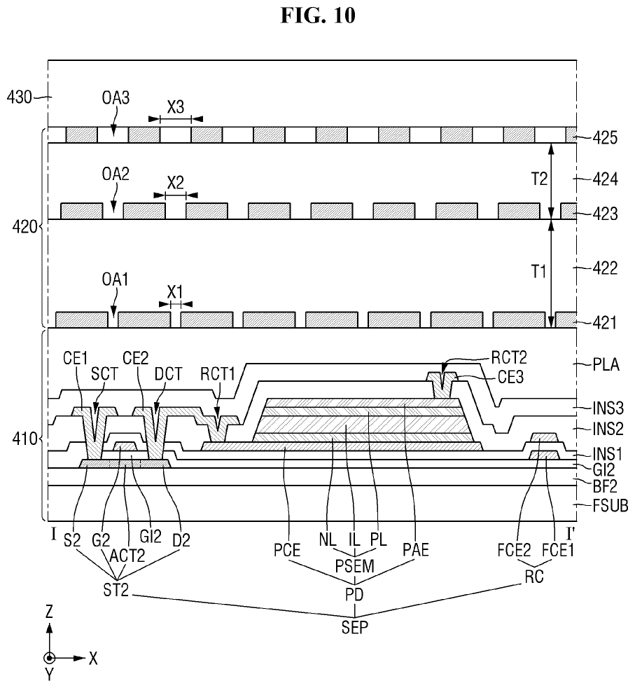

FIG. 10 is an enlarged cross-sectional view of a sixth embodiment of the fingerprint sensor 400 in area A of FIG. 3 in detail.

The embodiment of FIG. 10 is different from the embodiment of FIG. 5 in that third openings OA3 are the largest, first openings OA1 are the smallest, and a thickness T1 of a first light transmitting layer 422 is greater than a thickness T2 of a second light transmitting layer 424. That is, the embodiment of FIG. 10 is a combination of the embodiment of FIG. 7 and the embodiment of FIG. 9, and thus a description of the embodiment of FIG. 10 will be omitted to avoid redundancy.

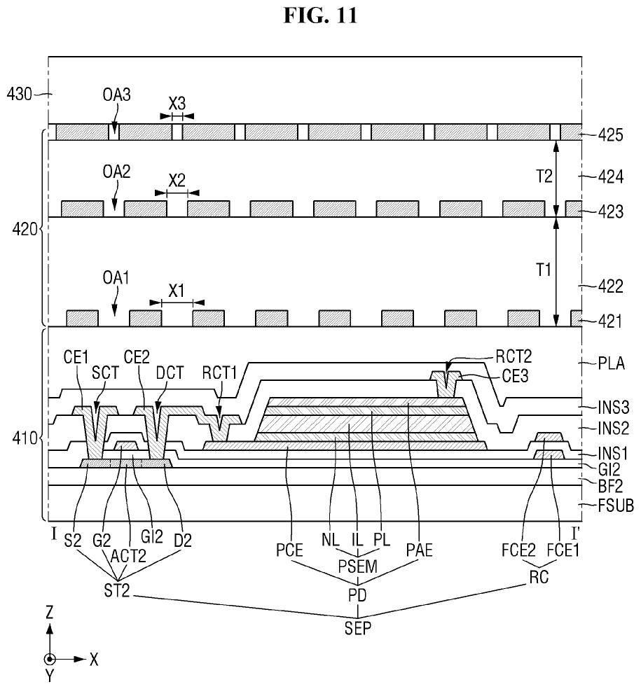

FIG. 11 is an enlarged cross-sectional view of a seventh embodiment of the fingerprint sensor 400 in area A of FIG. 3 in detail.

The embodiment of FIG. 11 is different from the embodiment of FIG. 5 in that first openings OA1 are the largest, third openings OA3 are the smallest, and a thickness T1 of a first light transmitting layer 422 is greater than a thickness T2 of a second light transmitting layer 424. That is, the embodiment of FIG. 11 is a combination of the embodiment of FIG. 8 and the embodiment of FIG. 9, and thus a description of the embodiment of FIG. 11 will be omitted to avoid redundancy.

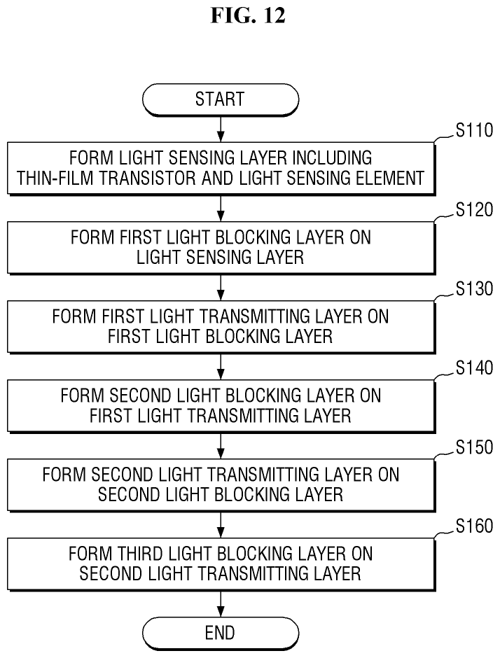

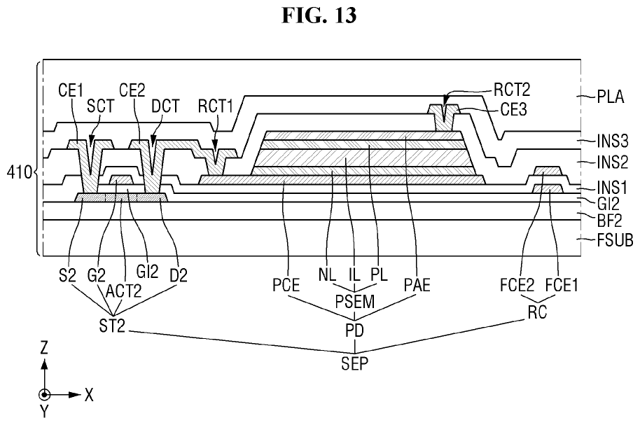

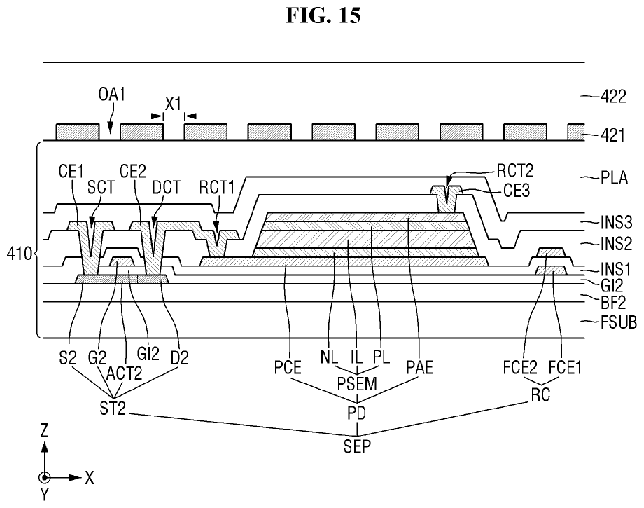

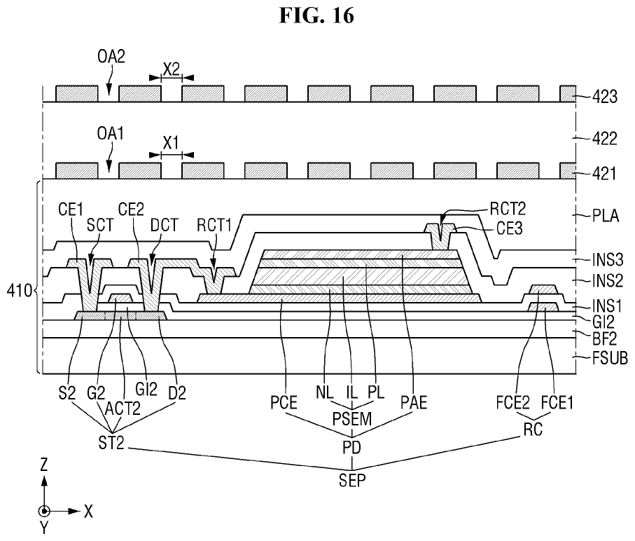

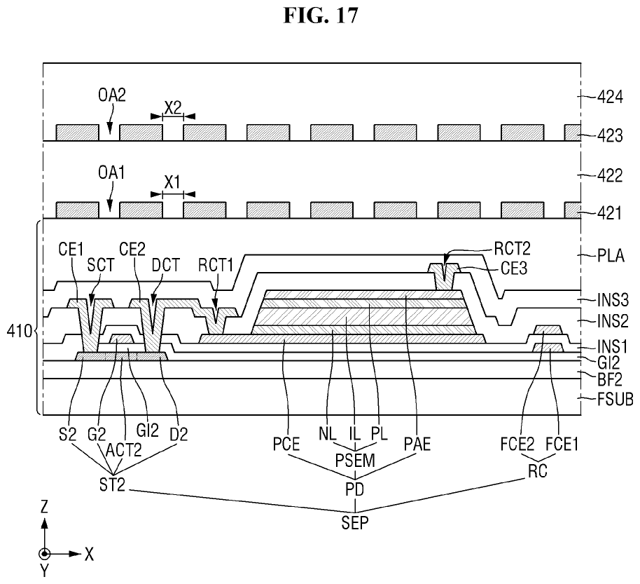

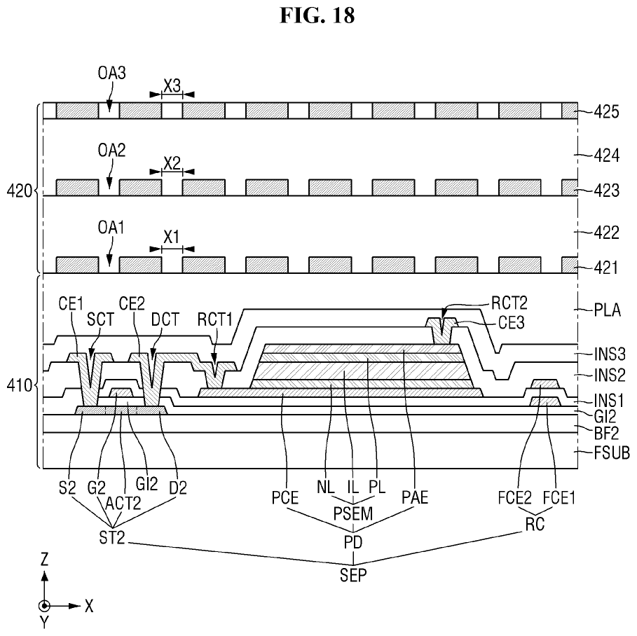

FIG. 12 is a flowchart illustrating a method of manufacturing a fingerprint sensor according to the principles of the invention. FIGS. 13 through 18 are cross-sectional views for explaining the method of manufacturing the fingerprint sensor of FIG. 12. For example, the cross-sectional views of FIGS.13 through 18 correspond to the embodiment shown in FIG. 5.

The method of manufacturing a fingerprint sensor 400 according to the embodiment will now be described in detail with reference to FIGS. 12 through 18.

First, a light sensing layer 410 including a second thin-film transistor ST2 and a light sensing element PD is formed (step S110 of FIG. 13).

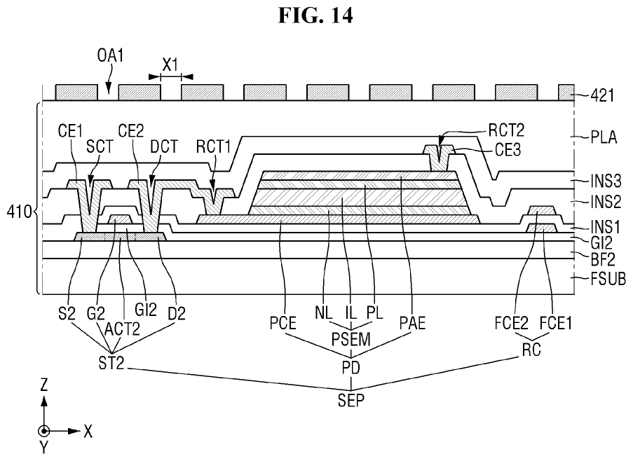

Referring to FIG. 14, a second buffer layer BF2 is formed on a fingerprint sensor substrate FSUB by depositing an inorganic material.

A second active layer ACT2 of the second thin-film transistor ST2 is formed on the second buffer layer BF2 by patterning a semiconductor material such as polycrystalline silicon, monocrystalline silicon, low-temperature polycrystalline silicon, amorphous silicon, or an oxide semiconductor using a photolithography process.

A second gate insulating layer GI2 is formed on the second active layer ACT2 of the second thin-film transistor ST2 by depositing an inorganic insulating material.

A second gate electrode G2 of the second thin-film transistor ST2 and a first fingerprint capacitor electrode FCE1 are formed on the second gate insulating layer GI2 by patterning a metal material using a photolithography process. The second active layer ACT2 of the second thin-film transistor ST2 which is not overlapped by the second gate electrode G2 in the third direction may be doped with impurities or ions to have conductivity. Therefore, a second source electrode S2 and a second drain electrode D2 of the second thin-film transistor ST2 having conductivity may be formed.

A first insulating layer INS1 is formed on the second gate electrode G2, the second source electrode S2, the second drain electrode D2, and the first fingerprint capacitor electrode FCE1 by depositing an inorganic insulating material.

A first sensing electrode PCE of the light sensing element PD and a second fingerprint capacitor electrode FCE2 are formed on the first insulating layer INS1 by patterning a metal material using a photolithography process. A sensing semiconductor layer PSEM is formed on the first sensing electrode PCE by patterning a semiconductor material using a photolithography process. A second sensing electrode PAE is formed on the sensing semiconductor layer PSEM by patterning a metal material using a photolithography process.

A second insulating layer INS2 is formed on the light sensing element PD and the second fingerprint capacitor electrode FCE2 by depositing an inorganic insulating material.

A source contact hole SCT, a drain contact hole DCT, a first sensing contact hole RCT1, and a second sensing contact hole RCT2 are formed in the second insulating layer INS2 using a photolithography process. The source contact hole SCT and the drain contact hole DCT may be formed by removing the first insulating layer INS1 and the second insulating layer INK. The first sensing contact hole RCT1 and the second sensing contact hole RCT2 may be formed by removing the second insulating layer INS2.

A first connection electrode CE1, a second connection electrode CE2, and a third connection electrode CE3 are formed on the second insulating layer INS2 by patterning a metal material using a photolithography process. The first connection electrode CE1 may be connected to the second source electrode S2 of the second thin-film transistor ST2 through the source contact hole SCT. The second connection electrode CE2 may be connected to the second drain electrode D2 of the second thin-film transistor ST2 through the drain contact hole DCT and may be connected to the first sensing electrode PCE through the first sensing contact hole RCT1. The third connection electrode CE3 may be connected to the second sensing electrode PAE through the second sensing contact hole RCT2.

A third insulating layer INS3 is formed on the first connection electrode CE1, the second connection electrode CE2, and the third connection electrode CE3 by depositing an inorganic insulating material. The third insulating layer INS3 can be omitted.

A planarization layer PLA is formed on the third insulating layer INS3 by depositing an organic material.

Second, a first light blocking layer 421 having first openings OA1 is formed on the planarization layer PLA of the light sensing layer 410 by patterning a metal material using a photolithography process (step S120 of FIG. 12).

Third, a first light transmitting layer 422 is formed on the first light blocking layer 421 by depositing an organic material (step S130 of FIG. 12).

Fourth, a second light blocking layer 423 having second openings OA2 is formed on the first light transmitting layer 422 by patterning a metal material using a photolithography process (step S140 of FIG. 12).

Fifth, a second light transmitting layer 424 is formed on the second light blocking layer 423 by depositing an organic material (step S150 of FIG. 12).

Sixth, a third light blocking layer 425 having third openings OA3 is formed on the second light transmitting layer 424 by patterning a metal material using a photolithography process (step S160 of FIG. 12).

As illustrated in FIGS. 12 through 18, the first light blocking layer 421, the second light blocking layer 423, and the third light blocking layer 425 are formed using a metal material. That is, since the first light blocking layer 421, the second light blocking layer 423, and the third light blocking layer 425 are not made of photosensitive resin capable of blocking light, for example, an organic material including an inorganic black pigment such as carbon black or an organic black pigment, equipment contamination does not occur when the first light blocking layer 421, the second light blocking layer 423, and the third light blocking layer 425 of a light guide layer 420 are formed. Therefore, a manufacturing device for forming the second thin-film transistor ST2, the light sensing element PD and a sensing capacitor RC of each sensor pixel SEP of the light sensing layer 410 can also be used as a manufacturing device for forming the light guide layer 420. Thus, the fingerprint sensor 400 including the light guide layer 420 can be manufactured without adding a separate manufacturing device.

In addition, as illustrated in FIGS. 12 through 18, when the first openings OA1, the second openings OA2, and the third openings OA3 have substantially the same size, the first light blocking layer 421, the second light blocking layer 423, and the third light blocking layer 425 can be formed using the same mask. Therefore, the cost of manufacturing the fingerprint sensor 400 can be reduced.

In a fingerprint sensor, a method of manufacturing the fingerprint sensor, and a display device including the fingerprint sensor according to the principles and some embodiments of the invention, a first light blocking layer having first openings, a second light blocking layer having second openings, and a third light blocking layer having third openings are formed in a light guide layer using a metal material. That is, the first light blocking layer, the second light blocking layer, and the third light blocking layer are not made of photosensitive resin capable of blocking light, for example, an organic material including an inorganic black pigment such as carbon black or an organic black pigment. Hence, equipment contamination does not occur when the first light blocking layer, the second light blocking layer, and the third light blocking layer are formed. Therefore, a manufacturing device for forming thin-film transistors and light sensing elements can also be used as a manufacturing device for forming the light guide layer. Thus, a fingerprint sensor including the light guide layer can be manufactured without adding a separate manufacturing device.

Although certain embodiments and implementations have been described herein, other embodiments and modifications will be apparent from this description. Accordingly, the inventive concepts are not limited to such embodiments, but rather to the broader scope of the appended claims and various obvious modifications and equivalent arrangements as would be apparent to a person of ordinary skill in the art.

What is claimed is:

1. A fingerprint sensor for a display device, the fingerprint sensor comprising:
a light sensor including a light sensing element through which a sensing current flows according to the intensity of incident light; and
a light guide disposed on the light sensor,
wherein the light guide comprises:
a first light blocking member having a first opening;
a first light transmitting member disposed on the first light blocking member; and
a second light blocking member disposed on the first light transmitting member and having a second opening overlapping the first opening.

2. The fingerprint sensor of claim 1, wherein the second opening has a size smaller or larger than that of the first opening.

3. The fingerprint sensor of claim 1, wherein the light sensor comprises a light sensing layer, the light guide comprises a light guide layer, the first light blocking member comprises a first light blocking layer, the first light transmitting member comprises a first light transmitting layer, and the second light blocking member comprises a second light blocking layer.

4. The fingerprint sensor of claim 3, further comprising:
a second light transmitting layer disposed on the second light blocking layer; and
a third light blocking layer disposed on the second light transmitting layer and having a third opening.

5. The fingerprint sensor of claim 4, wherein the third opening overlaps the first opening and the second opening, and the third opening has a size substantially the same as that of the first opening and that of the second opening.

6. The fingerprint sensor of claim 4, wherein the third opening overlaps the first opening and the second opening, and the third opening has a size larger than that of the second opening, and the size of the second opening is larger than the size of the first opening.

7. The fingerprint sensor of claim 4, wherein the third opening overlaps the first opening and the second opening, and the size of the third opening is smaller than the size of the second opening, and the size of the second opening is smaller than the size of the first opening.

8. The fingerprint sensor of claim 4, wherein the first light transmitting layer has a thickness greater than that of the second light transmitting layer, and at least one of the first, second and third light blocking layers is metallic.

9. A fingerprint sensor for a display device, the fingerprint sensor comprising:
a light sensor including a light sensing element through which a sensing current flows according to the intensity of incident light; and
a light guide disposed on the light sensor,
wherein the light guide comprises:
a first light blocking member having a first opening;
a first light transmitting member disposed on the first light blocking member;
a second light blocking member disposed on the first light transmitting member and having a second opening overlapping the first opening;
a second light transmitting member disposed on the second light blocking member; and
a third light blocking member disposed on the second light transmitting member and having a third opening,
wherein the first light transmitting member has a thickness greater than that of the is second light transmitting member.

10. The fingerprint sensor of claim 9, wherein the third opening overlaps the first opening and the second opening, and the third opening has a size substantially the same as that of the first opening and that of the second opening.

11. The fingerprint sensor of claim 9, wherein the third opening overlaps the first opening and the second opening, and the third opening has a size larger than that of the second opening, and the second opening has a size larger than that of the first opening.

12. The fingerprint sensor of claim 9, wherein the third opening overlaps the first opening and the second opening, and the size of the third opening is smaller than that of the second opening, and the second opening has a size smaller than that of the first opening.

13. A display device comprising:
a display panel to display an image; and
a fingerprint sensor comprising a light sensor including a light sensing element through which a sensing current flows according to the amount of light that passes through the display panel and a light guide disposed on the light sensor,
wherein the light guide comprises:
a first light blocking member having a first opening;
a first light transmitting member disposed on the first light blocking member; and
a second light blocking member disposed on the first light transmitting member and having a second opening overlapping the first opening.

14. The display device of claim 13, wherein the second opening has a size smaller or larger than that of the first opening.

15. The display device of claim 13, wherein the light sensor comprises a light sensing layer, the light guide comprises a light guide layer, the first light blocking member comprises a first light blocking layer, the first light transmitting member comprises a first light transmitting layer, and the second light blocking member comprises a second light blocking layer.

16. The display device of claim 13, further comprising:
a second light transmitting layer disposed on the second light blocking layer; and
a third light blocking layer disposed on the second light transmitting layer and having a third opening overlapping the first opening and the second opening.

17. The display device of claim 16, wherein the first light transmitting layer a thickness greater than that of the second light transmitting layer, and at least one of the first, second and third light blocking layers is metallic.

18. A method of manufacturing a fingerprint sensor, the method comprising the steps of:
forming a light sensing layer including a light sensing element through which a sensing current flows according to the intensity of incident light;
forming a first light blocking layer having a first opening on the light sensing layer;
forming a first light transmitting layer on the first light blocking layer; and
forming a second light blocking layer having a second opening on the first light transmitting layer, the second opening overlapping the first opening, wherein at least one of the first and second light blocking layers is formed from a metallic material

19. The method of claim 18, further comprising the steps of:
forming a second light transmitting layer on the second light blocking layer; and
forming a third light blocking layer having a third opening on the second light transmitting layer,
wherein the third opening overlaps the first opening and the second opening, and the third opening has a size different from that of the first opening and from that of the second opening.

20. The method of claim 19, wherein the first light transmitting layer has a thickness greater than that of the second light transmitting layer.
